(19) United States
(12) Patent Application Publication
(10) Pub. No.: US 2010/0248458 A1
(43) Pub. Date: Sep. 30, 2010

(54) COATING APPARATUS AND COATING METHOD

(76) Inventors: Shinichi MITANI, Shizuoka (JP); Kunihiko SUZUKI, Shizuoka (JP); Toshiro TSUMORI, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/730,571

(22) Filed: Mar. 24, 2010

(30) Foreign Application Priority Data
Mar. 24, 2009 (JP) 2009-071133

(51) Int. Cl. H01L 21/205; C23C 16/34

(52) U.S. Cl. 438/478; 118/719; 257/E21.101; 977/755

(57) ABSTRACT

The present invention provides a coating apparatus capable of efficiently performing a deposition process and also provides an efficient coating method.

A coating apparatus 1 for performing a deposition process on substrates W placed in a coating chamber by metalorganic chemical vapor deposition includes three or more coating chambers, e.g., a first coating chamber 2, a second coating chamber 102, and a third coating chamber 202. These coating chambers are configured such that each coating chamber is controlled independently of the other coating chambers to form a different film on the substrates W by controlling at least the composition of the material gas, the flow rate of material gas, the temperature, and the pressure in the coating chamber. A cleaning unit 5 is provided outside the coating chambers 2, 102, 202 to clean the susceptor after the deposition process.

### BACKGROUND OF THE INVENTION

1. Field of the Invention

The present invention relates to a coating apparatus and a coating method.

2. Background Art

Epitaxial growth, which is one of the thin film crystal growth techniques, refers to a method of growing a crystal on a substrate so that the atomic arrangement of the crystal is matched to that of a crystal plane of the substrate. The types of known epitaxial growth include reduced pressure epitaxial vapor deposition and MOCVD (Metal Organic Chemical Vapor Deposition), which uses organic metal and gas as raw materials. These methods process substrates in atmospheres and pressures different from the atmosphere. Japanese Laid-Open Patent Publication No. 5-55148 (1993) discloses a single wafer processing apparatus of the multiple chamber type used for reduced pressure epitaxial vapor deposition. This apparatus includes an I/O port, or chamber, having a gate which is connected to the atmospheric side and can be opened and closed, and also includes a platform adjacent and connected to the I/O port and a plurality of reaction chambers adjacent and connected to the platform.

In the apparatus disclosed in the above publication, the gate of the I/O port is opened and a processed substrate and a substrate to be processed are transferred to and from the atmospheric side when other substrates are being processed in the processing chambers. After this transfer the gate of the I/O port is closed, and then the gate between the I/O port and the platform is opened after the pressure or atmospheric conditions in the I/O port have become identical to those in the platform. Then upon completion of the processing in one of the processing chambers, the gate connected between this processing chamber and the platform is opened, and the processed substrate in the processing chamber is transferred to the I/O port and at the same time a substrate to be processed is transferred from the I/O port to the processing chamber.

In conventional coating apparatus of the single wafer processing type, only a single substrate is fed into each processing chamber at one time, and these substrates are subjected to the same coating or deposition process in the processing chambers. For example, in the apparatus disclosed in the above patent publication, a single substrate is transferred into the I/O port at one time and then transferred into a processing chamber through the platform. The substrate is then subjected to a deposition process in the processing chamber. After the completion of the process, the substrate is retrieved from the processing chamber and transferred into the I/O port through the platform. At that time, another substrate is transferred into the processing chamber and subsequently subjected to a deposition process.

Therefore, for example, when a blue light emitting diode component is manufactured by MOCVD using this conventional technique, an n-type GaN layer, an MQW (Multi-Quantum Well) active layer, and a p-type GaN layer are sequentially deposited on a sapphire substrate with a buffer layer formed therein by using the same processing chamber.

However, in order to deposit different films in the same processing chamber, that is, for example, in order to deposit a Si-doped n-type GaN layer, an MQW active layer, which may include a Si- or Mg-doped InGaN layer, and a Mg-doped p-type GaN layer in the same processing chamber, it is necessary to replace one dopant with another and also replace one material gas with another when switching between these deposition processes, which requires time. It will be noted that if such gas replacement is not sufficiently completed, degradation of the performance of the product will result. Therefore, the time spent on the gas replacement should not be reduced unless it is certain that no problem arises. That is, in order to maintain the performance of the product at a high level, it is necessary to sufficiently increase the time spent on the gas replacement. It has been found, however, that this prevents sufficient increase in the operating rate of the apparatus. As a result, it has been difficult to improve the throughput of the product formed by the deposition process.

The present invention has been made in view of the above problems. It is, therefore, an object of the present invention is to provide a coating apparatus and coating method capable of efficiently performing a deposition process.

Another object of the present invention is to provide an MOCVD apparatus and MOCVD coating method capable of efficiently forming a high quality deposition.

Other objects and advantages of the present invention will become apparent from the following description.

### SUMMARY OF THE INVENTION

According to one aspect of the present invention, a coating apparatus for performing a deposition process on a substrate placed in a coating chamber by metalorganic chemical vapor deposition, comprises three or more the coating chambers. The three or more coating chambers are configured such that each coating chamber is controlled independently of the other coating chambers to form a different film on the substrate by controlling at least the composition of the material gas, the flow rate of material gas, the temperature, and the pressure in the coating chamber.

According to another aspect of the present invention, in a coating method, a susceptor with a substrate mounted thereon is automatically transferred from one to another of three or more different coating chambers such that a different film is deposited in a layer on the substrate in each coating chamber under different conditions by metalorganic chemical vapor deposition. A film attached to the surface of the susceptor is removed by using a cleaning unit provided outside the three or more coating chambers. The different films layered on the substrate are an n-type GaN layer, a multiquantum well (MQW) active layer, and a p-type GaN layer.

### BRIEF DESCRIPTION OF THE DRAWINGS

FIG. 1 is a schematic plan view of a coating apparatus according to an embodiment of the present invention.

FIG. 2 is a schematic cross-sectional view showing an exemplary layer configuration of a member manufactured by a coating method of the present embodiment.

### DETAILED DESCRIPTION OF THE EMBODIMENTS

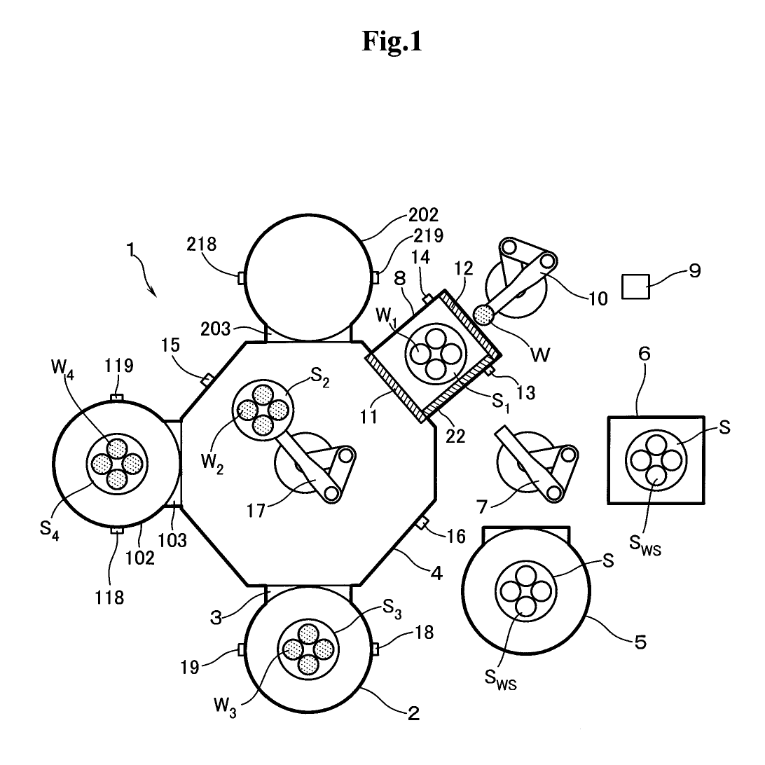

FIG. 1 is a schematic plan view of a coating apparatus 1 according to an embodiment of the present invention. As shown in this figure, the coating apparatus 1 includes: a first coating chamber 2, a second coating chamber 102, and a third coating chamber 202 for forming a film on the surfaces of substrates mounted on a susceptor; a substrate standby unit 4 connected through a first gate unit 3 to the first coating chamber 2, through a second gate unit 103 to the second coating chamber 102, and through a third gate unit 203 to the third coating chamber 202; and a cleaning unit 5 for cleaning the susceptor retrieved from each coating chamber through the substrate standby unit 4, particularly the susceptor retrieved from the third coating chamber 202 through the substrate standby unit 4.

The coating apparatus 1 performs deposition processes on substrates placed in its coating chambers by MOCVD, and one of the features of this coating apparatus 1 is that it includes three coating chambers, namely, the first to third coating chambers, each for forming a filmon the surfaces of the substrates mounted on a susceptor. The first coating chamber 2, the second coating chamber 102, and the third coating chamber 202 each have an introduction port and an exhaust port, which allows a different material gas of the desired composition to be introduced into each coating chamber at a suitable flow rate under suitably adjusted pressure conditions. Further, each coating chamber includes a heater selected by taking into account the heating temperature in the deposition process and its reactivity with the material gas and carrier gas, and each coating chamber is independently controlled so that the temperature in the chamber is adjusted to achieve suitable deposition conditions under which a deposition process is performed to form a desired layer on the surfaces of the substrates. The coating apparatus 1 is configured such that after a layer is deposited on substrates in the first coating chamber 2, another layer is deposited on the same substrates in the second coating chamber 102 and then still another layer is deposited on the substrates in the third coating chamber 202, thus completing a series of deposition processes on the substrates.

Another feature of the coating apparatus 1 is that a plurality of substrates are transferred into each of the first coating chamber 2, the second coating chamber 102, and the third coating chamber 202, and these substrates in each coating chamber are simultaneously subjected to a deposition process. That is, the present invention allows a deposition process to be performed on substrates in a manner which is a combination of a single substrate processing manner and a batch processing manner. This means that the coating apparatus 1 can perform a deposition process on a plurality of substrates at once, whereas conventional coating apparatus of the single wafer processing type can perform a deposition process on substrates only one at a time. In this way it is possible to increase the operating rate of the coating apparatus 1.

Still another feature of the coating apparatus 1 is that it includes the substrate standby unit 4 adjacent and connected to the first coating chamber 2, the second coating chamber 102, and the third coating chamber 202. The substrate standby unit 4 may be provided with heating units for heating the susceptors and substrates retrieved from the first coating chamber 2, the second coating chamber 102, and the third coating chamber 202. In such a case, the first gate unit 3, the second gate unit 103, and the third gate unit 203 can be opened to retrieve substrates and susceptors from the first coating chamber 2, the second coating chamber 102, and the third coating chamber 202, respectively, while the insides of these chambers are still relatively hot. That is, there is no need to wait for the temperature in the first to third coating chambers 2, 102, and 202 to sufficiently drop, making it possible to increase the operating rate of the coating apparatus 1 and improve the efficiency of the deposition processes.

Still another feature of the coating apparatus 1 is that susceptors are retrieved from the third coating chamber 202 and cleaned by the cleaning unit 5. This eliminates the need to interrupt the deposition processes each time a susceptor is cleaned, making it possible to continuously perform the series of deposition processes and thereby improve the efficiency of these processes.

According to the present embodiment, substrates and the susceptor on which the substrates are mounted are retrieved from the third coating chamber 202 after the substrates have been subjected to a series of deposition processes in the first to third coating chambers 2, 102, and 202. It should be noted that only substrates may be retrieved from the third coating chamber 202 after they have been subjected to the series of deposition processes until the susceptor has been used in a predetermined number of deposition processes, whereupon the susceptor and the substrates thereon may be both retrieved from the third coating chamber 202. The timing of when the susceptor is retrieved is preferably determined by the thickness of the film that has been formed on the surface of the susceptor. For example, the susceptor, together with the substrates thereon, may be retrieved from the third coating chamber 202 to clean the susceptor when the thickness of the film deposited on the susceptor has reached 100 μm. According to the present invention, the timing of when the susceptor is retrieved substantially does not affect the efficiency of each deposition process.

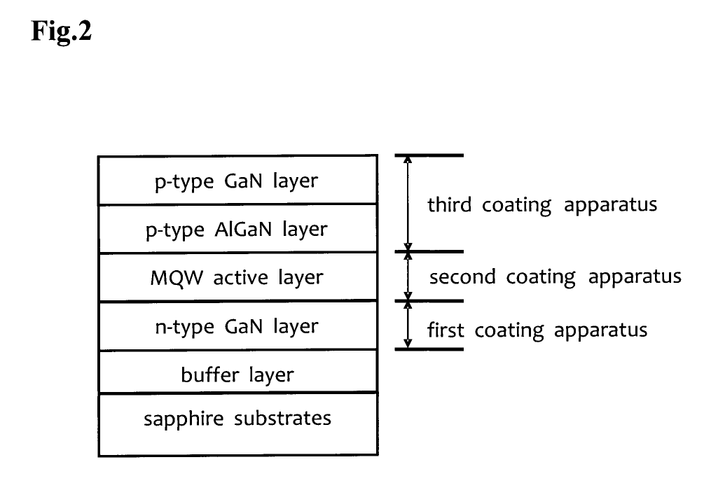

The operation of the coating apparatus 1 and a coating method of the present invention will be described in detail with reference to FIGS. 1 and 2.

A susceptor S to be used for supporting substrates W in the first coating chamber 2, the second coating chamber 102, and the third coating chamber 202 is stored in a susceptor standby chamber 6. This susceptor S is placed in the susceptor standby chamber 6 after the susceptor is cleaned by the cleaning unit 5 provided outside the first to third coating chambers 2, 102, and 202 and the substrate standby unit 4. When a deposition process is to be initiated, a susceptor transfer robot 7 retrieves the susceptor S from the susceptor standby chamber 6 and places it in a substrate/susceptor mounting unit 8.

On the other hand, substrates W to be subjected to a deposition process are stored in a cassette 9. When a film deposition process is to be initiated, a substrate transfer robot 10 retrieves the substrates W from the cassette 9 and places them on the susceptor S in the substrate/susceptor mounting unit 8. It should be noted that the transfer of the substrates W may be accomplished, e.g., by use of a Bernoulli chuck, which is capable of carrying a substrate without contacting it by ejecting gas. Further, the substrates W may be, e.g., sapphire (α-Al₂O₃), silicon carbide (SiC), zinc oxide (ZnO), etc., used for the manufacture of blue light emitting diodes. In the case of sapphire substrates, for example, an amorphous GaN buffer layer approximately 10 nm thick is formed on the surfaces of the substrates in order to allow high quality films to be subsequently formed over the substrates. This amorphous GaN buffer layer may be formed on the sapphire substrates under a low pressure of approximately 1.33×10⁴-2.67×10⁴ Pa (100-200 Torr) and at a low temperature of approximately 500° C. using hydrogen gas as a carrier gas after hydrogen radical cleaning is applied to the substrates using hydrogen gas at a temperature of approximately 500° C. This amorphous GaN buffer layer often transforms into a polycrystalline GaN buffer layer depending on the temperature conditions to which the amorphous GaN layer is subjected after its formation.

It is to be understood that in other embodiments of the present embodiment, the coating apparatus may include, in addition to the first to third coating chambers, a coating chamber for deposition by plasma CVD. With this arrangement, an amorphous GaN buffer layer may be formed on the surfaces of sapphire substrates in this coating chamber under the above conditions, and these substrates with the buffer layer formed thereon may then be subjected to a specific deposition process in each of the first to third coating chambers.

The substrate/susceptor mounting unit 8 is connected to the substrate standby unit 4 through a fourth gate unit 11. Further, the substrates W and the susceptor S can be transferred between the inside and outside of the substrate/susceptor mounting unit 8 by opening a fifth gate unit 12 or a sixth gate unit 22. Therefore, when the substrates W and the susceptor S are to be placed in the substrate/susceptor mounting unit 8 from the outside, the fourth gate unit 11 is closed or remains closed and the fifth gate unit 12 or the sixth gate unit 22 is opened to allow the substrates and susceptor to be transferred into the substrate/susceptor mounting unit 8. Thus, the substrate/susceptor mounting unit 8 can be used to prevent external air from directly entering the coating chamber 2. That is, moisture and organic matter in the air can be prevented from entering the first coating chamber 2, the second coating chamber 102, and the third coating chamber 202 and adversely affecting the deposition process therein. It should be noted that the coating apparatus 1 may include only one of the fifth and sixth gate units 12 and 22, and the substrates W and susceptor S may be both transferred through this gate unit.

A plurality of susceptors each having a plurality of substrates mounted thereon may be supplied to the coating apparatus 1. In the present embodiment, the coating apparatus 1 is shown to have placed therein a susceptor S₁ with substrates W₁ thereon, a susceptor S₂ with substrates W₂ thereon, a susceptor S₃ with substrates W₃ thereon, and a susceptor S₄ with substrates W₄ thereon. Specifically, the susceptor S₁ is placed in the substrate/susceptor mounting unit 8, the susceptor S₂ is placed in the substrate standby unit 4, the susceptor S₃ is placed in the first chamber 2, and the susceptor S₄ is placed in the second chamber 102, as shown in FIG. 1. It will be noted that the substrates W₁ are substrates which have not yet been subjected to any deposition process, the substrates W₂ are substrates which have been subjected to the series of deposition processes, and the substrates W₃ and W₄ are substrates which are being subjected to a deposition process. The following description will focus on the substrates W₁ and the susceptor S₁.

The susceptors of the present embodiment are constructed so that a plurality of substrates can be mounted thereon. For example, the susceptor S shown in FIG. 1 has 4 substrate mounting portions S_{ws} on which 4 substrates W can be respectively mounted at once. Likewise, 4 substrates W₁, 4 substrates W₂, 4 substrates W₃, and 4 substrates W₄ are mounted on the susceptors S₁, S₂, S₃, and S₄, respectively. Thus, the structure of the susceptors allows 4 substrates to be transferred into the substrate/susceptor mounting unit 8 simultaneously.

The maximum number of substrates that can be mounted on each susceptor, that is, the number of substrate mounting portions S_{ws} of the susceptor, may be determined by the size of the substrates. Further, the number of substrate mounting portions S_{ws} of each susceptor may be determined by the required thickness uniformity of the film formed in each coating chamber or the required efficiency of the deposition process in each coating chamber. The more substrate mounting portions S_{ws} the more substrates can be brought into the coating chambers. However, if too many substrates are supplied to the coating chambers, there will be some lack of uniformity in thickness of the film formed on these substrates. If, on the other hand, the number of substrate mounting portions S_{ws} is too small, only a limited number of substrates can be supplied to the coating chambers, resulting in decreased efficiency of the deposition processes. In the case where sapphire substrates are processed for the manufacture of blue light emitting diodes, the number of substrate mounting portions S_{ws} of each susceptor is preferably approximately 4-5.

The fifth gate unit 12 and the sixth gate unit 22 are closed after the susceptor S1 with the substrates W1 mounted thereon is transferred into the substrate/susceptor mounting unit 8. Air is then evacuated from the substrate/susceptor mounting unit 8 through an exhaust port 13 by use of a vacuum pump, etc. Next, hydrogen gas serving as a carrier gas is introduced into the substrate/susceptor mounting unit 8 through an introduction port 14. It should be noted that the introduction port 14 is connected through piping (not shown) to a steel bottle containing hydrogen gas and that containing nitrogen gas so that the hydrogen gas or nitrogen gas can be introduced into the substrate/susceptor mounting unit 8 as a carrier gas.

The substrate standby unit 4 also has an introduction port 15 and an exhaust port 16. The introduction port 15 is connected through piping (not shown) to a steel bottle containing hydrogen gas and that containing nitrogen gas so that the hydrogen gas or nitrogen gas can be introduced into the substrate standby unit 4 as a carrier gas. Further, the exhaust port 16 is connected through piping (not shown) to a vacuum pump (not shown) so that gas can be evacuated from the substrate standby unit 4.

A substrate/susceptor transfer robot 17 serving as transfer units of the present invention is installed in the substrate standby unit 4. The substrate/susceptor transfer robot 17 is made of a heat resistant material, e.g., silicon-coated carbon. The substrate/susceptor transfer robot 17 may be constructed to include a heater (or heating units) in the portion thereof for mounting a susceptor thereon so that the susceptor and the substrates thereon can be prevented from undergoing a radical temperature change when they are mounted on the robot even if they have just been retrieved from the coating chambers and hence are still hot.

After the susceptor S₁ with the substrates W₁ mounted thereon has been transferred into the substrate/susceptor mounting unit 8, the fourth gate unit 11 is opened when the pressure and atmospheric conditions in the substrate/susceptor mounting unit 8 have substantially identical to those in the substrate standby unit 4. It should be noted that the substrate/susceptor mounting unit 8 may have fixed therein two parallel upper and lower members each for supporting the lower surfaces of the peripheral portions of substrates in order to facilitate the swapping of the susceptor S₁ and the susceptor S₂ which has just been used in the series of deposition processes. Specifically, first, the susceptor S₂ with the substrates W₂ thereon, which has been retrieved from the third coating chamber 202 through the third gate unit 203 by the substrate/susceptor transfer robot 17 after the substrates W₂ have been subjected to the series of deposition processes, is transferred into the substrate/susceptor mounting unit 8 and then mounted on the lower member. The third gate unit 203 and the fourth gate unit 11 are then closed.

Next, after the process in the second coating chamber 102 has been completed, the second gate unit 103 is opened and the susceptor S₄ with the substrates W₄ mounted thereon is transferred into the substrate standby unit 4 by the substrate/susceptor transfer robot 17. At that time, the portion of the substrate/susceptor transfer robot 17 on which the susceptor S₄ is mounted may be heated by a heater beforehand to prevent the hot substrates W₄ and the hot susceptor S₄ from undergoing a radical temperature change. Then, the third gate unit 203 is opened and the susceptor S₄ with the substrates W₄ thereon is transferred into the third coating chamber 202 by the substrate/susceptor transfer robot 17. The third gate unit 203 and the second gate unit 103 are then closed.

Next, after the process in the first coating chamber 2 has been completed, the first gate unit 3 is opened and the susceptor S₃ with the substrates W₃ mounted thereon is transferred into the substrate standby unit 4 by the substrate/susceptor transfer robot 17. At that time, the portion of the substrate/susceptor transfer robot 17 on which the susceptor S₃ is mounted may be heated by a heater beforehand to prevent the hot substrates W₃ and the hot susceptors S₃ from undergoing a radical temperature change. Then, the second gate unit 103 is opened and the susceptor S₃ with the substrates W₃ thereon is transferred into the second coating chamber 102 by the substrate/susceptor transfer robot 17. The second gate unit 103 and the first gate unit 3 are then closed.

Next, the fourth gate unit of the substrate/susceptor mounting unit 8 is opened and the susceptor S₁ with the substrates W₁ mounted thereon is transferred into the substrate standby unit 4 by the substrate/susceptor transfer robot 17. The first gate unit 3 is then opened and the susceptor S₁ with the substrates W₁ thereon is transferred into the first coating chamber 2 by the substrate/susceptor transfer robot 17. The fourth gate unit 11 and the first gate unit 3 are then closed.

The first coating chamber 2 has an introduction port 18 and an exhaust port 19. The introduction port 18 is connected through piping (not shown) to a steel bottle containing a material gas and to a steel bottle from which nitrogen gas or hydrogen gas serving as a carrier gas can be supplied. A suitable amount of such gas is supplied as necessary. Further, the exhaust port 19 is connected through piping (not shown) to a vacuum pump (not shown) so that gas can be evacuated from the first coating chamber 2 through the exhaust port 19 and so that a suitable reduced pressure environment can be created. The susceptor S₁ is mounted on a rotatable susceptor table (not shown) installed in the first coating chamber 2. The substrates W₁ can be heated by a heater (not shown) selected by taking into account the heating temperature in the deposition process and its unreactivity with the material gas and the reactant gas supplied. After the susceptor S₁ with the substrates W₁ thereon has been placed in the first coating chamber 2, these substrates W₁ are subjected to a predetermined deposition process with the first gate unit 3 closed. In the example shown in FIG. 1, 4 substrates can be subjected to a deposition process at the same time.

The second coating chamber 102 has an introduction port 118 and an exhaust port 119. The introduction port 118 is connected through piping (not shown) to a steel bottle containing a material gas and to a steel bottle from which nitrogen gas or hydrogen gas serving a carrier gas can be supplied. A suitable amount of such gas is supplied as necessary. Further, the exhaust port 119 is connected through piping (not shown) to a vacuum pump (not shown) so that gas can be evacuated from the second coating chamber 102 through the exhaust port 119 and so that a suitable reduced pressure environment can be created.

The susceptor S₃ is mounted on a rotatable susceptor table (not shown) installed in the second coating chamber 102. The substrates W₃ can be heated by a heater (not shown) selected by taking into account the heating temperature in the deposition process and its unreactivity with the material gas and the reactant gas supplied. After the susceptor S₃ with the substrates W₃ thereon has been placed in the second coating chamber 102, these substrates W₃ are subjected to a predetermined deposition process with the second gate unit 103 closed. In the example shown in FIG. 1, 4 substrates can be subjected to a deposition process at the same time.

The third coating chamber 202 has an introduction port 218 and an exhaust port 219. The introduction port 218 is connected through piping (not shown) to a steel bottle containing a material gas and to a steel bottle from which nitrogen gas or hydrogen gas serving as a carrier gas can be supplied. A suitable amount of such gas is supplied as necessary. Further, the exhaust port 219 is connected through piping (not shown) to a vacuum pump (not shown) so that gas can be evacuated from the third coating chamber 202 and so that a suitable reduced pressure environment can be created.

The susceptor S₄ is mounted on a rotatable susceptor table (not shown) installed in the third coating chamber 202. The substrates W₄ can be heated by a heater (not shown) selected by taking into account the heating temperature in the deposition process and its unreactivity with the material gas and the reactant gas supplied. After the susceptor S₄ with the substrates W₄ thereon has been placed in the third coating chamber 202, these substrates W₄ are subjected to a predetermined deposition process with the third gate unit 203 closed. In the example shown in FIG. 1, 4 substrates can be subjected to a deposition process at the same time.

The substrates W₁ on the susceptor S₁ will now be further described. These substrates W₁, together with the susceptor S₁ on which they are mounted, are transferred into the second coating chamber 102 in the same manner as described above in connection with the substrates W₃ on the susceptor S₃ and are subjected to the same deposition process as that to which the substrates W₃ on the susceptor S₃ were subjected as previously described. The substrates W₁, together with the susceptor S₁ on which they are mounted, are then transferred into the third coating chamber 202 and subjected to the same deposition process as that to which the substrates W₄ on the susceptor S₄ were subjected as described above. After thus being subjected to the series of deposition processes, the substrates W₁, together with the susceptor S₁ on which they are mounted, are retrieved from the third coating chamber 202 through the third gate unit 203 by the substrate/susceptor transfer robot 17. After retrieving the susceptor S₁ with the substrates W₁ thereon from the third coating chamber 202, the third gate unit 203 is closed and the temperature of the heater in the substrate standby unit 4 is gradually decreased. After the susceptor S₁ and the substrates W₁ have sufficiently cooled, the fourth gate unit 11 is opened and the susceptor S₁ with the substrates W₁ thereon is transferred into the substrate/susceptor mounting unit 8 and mounted at a predetermined location by the substrate/susceptor transfer robot 17.

Next, the fourth gate unit 11 is closed and nitrogen gas is introduced into the substrate/susceptor mounting unit 8 through the introduction port 14 to increase the pressure in the substrate/susceptor mounting unit 8 back to atmospheric pressure. The fifth gate unit 12 is then opened, and the substrates W₁, which have been subjected to the series of deposition processes, are placed at a predetermined location in the cassette 9 by the substrate transfer robot 10. The susceptor S₁, on the other hand, is transferred into the cleaning unit 5 through the sixth gate unit 22 by the susceptor transfer robot 7.

In the cleaning unit 5, the film formed on the surface of the susceptor S₁ is etched away. Though not shown in detail, the cleaning unit 5 includes a plasma reaction chamber. The susceptor is heated to a predetermined temperature by a heater, and at the same time gas is evacuated from the plasma reaction chamber through the exhaust port and an etching gas is introduced into the plasma reaction chamber through the introduction port. The etching gas may be, e.g., a gas mixture of CF₄, NO₂, and SiH₄, or a gas mixture of SF₄ and O₂. A high frequency voltage is applied to the electrodes provided in the plasma reaction section to generate plasma and thereby etch away the film and dirt deposited on the surface of the susceptor S₁ and clean the susceptor S₁. It should be noted that if ClF₃ gas is used as the etching gas, the etching process does not require heating, eliminating the need for a heater in the cleaning unit 5. Upon completion of the cleaning of the susceptor S₁, the cleaned susceptor S₁ is transferred into the susceptor standby chamber 6 by the susceptor transfer robot 7.

Though not described above, the susceptor S₂ with the substrates W₂ thereon, the susceptor S₃ with the substrates W₃ thereon, and the susceptor S₄ with the substrates W₄ thereon are also transferred from the substrate/susceptor mounting unit 8 into the atmosphere in the same manner as is the susceptor S₁ with the substrates W₁ thereon. The substrates W₂, W₃, and W₄ are then placed at a predetermined location in the cassette 9. The susceptors S₂, S₃, and S₄, on the other hand, are placed in the susceptor standby chamber 6 after the film and dirt attached to their surfaces are removed in the cleaning unit 5. The cleaning process in the cleaning unit 5 is performed while other substrates are processed in the coating chambers. That is, the cleaning process does not require the deposition processes to be interrupted, thus increasing the operating rate of the first to third coating chambers and efficiently performing the deposition processes. On the other hand, the substrates W to be subsequently subjected to the deposition processes and the susceptor S for these substrates W are retrieved from the cassette 9 and the susceptor standby chamber 6, respectively, and transferred into the substrate standby unit 4 and the substrate/susceptor mounting unit 8 in the same manner as described above.

There will be described in detail the deposition process and deposition method performed on the substrates W₁ mounted on the susceptor S₁ in each of the first to third coating chambers.

The deposition processes to which the substrates W₁ mounted on the susceptor S₁ are subjected are adapted to manufacture a blue light emitting diode component in the above coating apparatus 1 by MOCVD. FIG. 2 is a schematic cross-sectional view showing an exemplary layer configuration of a member manufactured by a coating method of the present embodiment.

The substrates may be sapphire substrates. According to the present embodiment, these sapphire substrates have an amorphous GaN buffer layer approximately 10 nm thick formed on the surface thereof in order to allow high quality films to be subsequently formed over the substrates. This amorphous GaN buffer layer may be formed on the sapphire substrates under a low pressure of approximately 1.33×10⁴-2.67×10⁴ Pa (100-200 Torr) and at a low temperature of approximately 500° C. using hydrogen gas as a carrier gas after hydrogen radical cleaning is applied to the surfaces of the sapphire substrates using hydrogen gas at a temperature of approximately 500° C.

These sapphire substrates with the buffer layer formed thereon are mounted on a susceptor, as described above, and the susceptor with the substrates thereon is transferred into the first coating chamber 2 in the coating apparatus 1 and mounted on the susceptor table of the first coating chamber 2. The first coating chamber 2 has a tungsten heater, which is suitable for use in high temperature processes. The sapphire substrates are then heated to a high temperature of 1050±1° C. under a reduced pressure of approximately 1.33×10⁴-2.67×10⁴ Pa (100-200 Torr) while hydrogen gas serving as a carrier gas is introduced into the first coating chamber 2. It should be noted that the heater for heating the substrates may be an RF coil or a molybdenum heater, which are also suitable for use in high temperature processes. A material gas is then introduced into the first coating chamber 2 while rotating all sapphire substrates by rotating the susceptor table on which they are mounted, thereby depositing an n-type GaN layer with a uniform thickness on all sapphire substrates. It should be noted that the material gas is introduced from the shower head (not shown) provided at the top of the first coating chamber 2 such that the gas flows perpendicular to the sapphire substrates. Further, the susceptor table is rotated, e.g., at a high speed of 300-1000 rpm in the deposition process. The thickness of the n-type GaN layer may be, e.g., 3-4 μm. The material gas may include, e.g., trimethyl gallium (TMG) as the Group III material gas, ammonia (NH₃) as the Group V material gas, and Si as the n-type dopant.

After the deposition of the n-type GaN layer on the sapphire substrates, the susceptor with the processed substrates thereon is retrieved from the first coating chamber 2 and transferred into the second coating chamber 102. The susceptor with the substrates thereon is then mounted on the susceptor table in the second coating chamber 102. The sapphire substrates are then heated to a relatively low temperature of (700-800° C.) ±1° C. under normal pressure conditions while nitrogen gas serving as a carrier gas is introduced into the second coating chamber 102. It should be noted that the second coating chamber 102 has an SiC heater for heating the substrates.

If a tungsten heater, a molybdenum heater, or an RF heater is used in the second coating chamber 102, their constituent materials such as tungsten might react with nitrogen under heated conditions, resulting in degradation (or embrittlement) of the heater. Therefore, an SiC heater is preferably used in the second coating chamber 102. Further, SiC heaters are characterized by their high degree of design freedom due to their manufacturing method and allow a uniform temperature distribution to be easily established across the surface of the susceptor. Therefore, they are suitable for forming thin films having uniform characteristics. Furthermore, since the SiC material of SiC heaters generally contains little impurities, the use of an SiC heater does not pose a significant risk of adversely affecting the deposition process on the substrates. Therefore, SiC heaters are suitable for use in the second coating chamber 102 in which nitrogen gas is used as a carrier gas.

A material gas is introduced into the second coating chamber 102 while rotating all sapphire substrates by rotating the susceptor table on which they are mounted, thereby depositing a uniform MQW active layer on all sapphire substrates. It should be noted that the material gas is introduced from the shower head (not shown) provided at the top of the second coating chamber 102 such that the gas flows perpendicular to the sapphire substrates. Further, the susceptor table is rotated, e.g., at a high speed of 300-1000 rpm in the deposition process. The MQW active layer of the present embodiment has an MQW structure containing InGaN and serves to amplify the light generated as a result of recombination of electrons and holes. The MQW active layer is a multilayer film that includes approximately 20 alternating layers, a few nm to a few tens of nm thick, of two different materials, namely, InGaN and GaN, or alternatively InGaN and (In) GaN which have different In mole percentages. The InGaN layers have an In mole percentage of approximately 15% and hence has a relatively small bandgap, which allows the MQW active layer to have a well layer structure. The (In) GaN layers form barrier layers in the MQW active layer. The material gas for depositing the MQW active layer may include, e.g., trimethyl gallium (TMG) as the Group III material gas, trimethyl indium (TMI), and ammonia (NH₃) as the Group V material gas.

Each of the first to third coating chambers has an introduction port for introducing a carrier gas and a material gas into the chamber, as described above. Further, a shower head (not shown) is provided at the tip of the introduction port in each coating chamber. In order for the shower head to apply the material gas uniformly across the substrates in the coating chamber, the material gas which has been externally supplied to the coating chamber through piping is passed through the buffer in the shower head and then ejected from a plurality of through-holes of the shower head. At that time, the inside of the coating chamber is usually at a high temperature of 1000° C. or more, as in the case with the first coating chamber 2 described above. Therefore, the shower head generally must be made of metal such as an aluminum alloy and must have a water cooled structure. However, since the inside of the second coating chamber 102 is at a relatively low temperature of (700-800° C.) ±1° C., the shower head of this chamber need not have a water cooled structure and can be manufactured from a highly pure material, e.g., quartz, etc. Therefore, the second coating chamber 102 can have a simple structure as compared with other coating chambers in which a high temperature process is carried out. Furthermore, since less metal is exposed to the inside of the coating chamber, the deposition process in the chamber may be affected by less contaminants.

After the deposition of the MQW active layer on the sapphire substrates, the susceptor with the processed substrates thereon is retrieved from the second coating chamber 102 and transferred into the third coating chamber 202. The susceptor with the substrates thereon is then mounted on the susceptor table in the third coating chamber 202. The third coating chamber 202 has a tungsten heater, which is suitable for use in high temperature processes. The sapphire substrates which have been subjected to the deposition processes in the first and second coating chambers are then heated to a high temperature of 1000±1° C. under substantially normal pressure conditions (slightly reduced pressure conditions) while hydrogen gas serving as a carrier gas is introduced into the third coating chamber. It should be noted that the heater for heating the substrates may be an RF coil or a molybdenum heater, which are also suitable for use in high temperature processes.

A material gas is then introduced into the third coating chamber 202 while rotating all sapphire substrates by rotating the susceptor table on which they are mounted, thereby depositing a p-type semiconductor layer with a uniform thickness on all sapphire substrates. It should be noted that the material gas is introduced from the shower head (not shown) provided at the top of the third coating chamber 202 such that the gas flows perpendicular to the sapphire substrates. Further, the susceptor table is rotated, e.g., at a high speed of 300-1000 rpm in the deposition process. The p-type semiconductor layer is made up of a p-type AlGaN layer and a p-type GaN layer deposited on the p-type AlGaN layer. The p-type semiconductor layer has a thickness of approximately 1 μm and is formed on the MQW active layer on the sapphire substrates which have been subjected to the deposition processes in the first and second coating chambers. The material gas may include, e.g., trimethyl gallium (TMG) and trimethyl aluminum (TMA) as the Group III material gas, ammonia (NH₃) as the Group V material gas, and Mg as the p-type dopant.

The deposition of the p-type semiconductor layer on the sapphire substrates completes the series of deposition processes. The resulting sapphire substrates have deposited thereon successively the n-type GaN layer, the MQW active layer, and the p-type semiconductor, which includes the p-type AlGaN layer and the p-type GaN layer deposited on the p-type AlGaN layer. These processed substrates are then retrieved from the third coating chamber 202, transferred into the substrate/susceptor mounting unit 8, and mounted at a predetermined location by the substrate/susceptor transfer robot 17.

The processed sapphire substrates are then placed at a predetermined location in the cassette 9 by the substrate transfer robot 10, as described above. The susceptor, on the other hand, is transferred into the cleaning unit 5 by the susceptor transfer robot 7 and cleaned by the cleaning unit 5.

This completes the description of the coating method for manufacturing a blue light emitting diode component by MOCVD. In this method, an n-type semiconductor layer, an MQW active layer, and a p-type semiconductor layer are deposited in separate coating chambers. According to a conventional coating method using a conventional coating apparatus, all of these deposition processes are carried out in a single coating chamber. This means that it is necessary to replace one dopant gas with another when switching between the process of forming an n-type film and that of forming a p-type film. If such gas replacement is not sufficiently completed, the resulting component has degraded performance. On the other hand, the coating method using the coating apparatus of the present embodiment allows each deposition process to be performed in a separate coating chamber, thereby reducing the time required for gas replacement. This makes it possible to increase the efficiency of the deposition processes and facilitates improving the performance of the manufactured component.

It will be understood that the present invention is not limited to the embodiment described above since various alterations may be made thereto without departing from the spirit and scope of the invention.

For example, although the above embodiment uses sapphire substrates, it is to be understood that other embodiments may use undoped GaN substrates, instead of sapphire substrates, in order to improve the luminous efficiency.

Further, since the construction of the light emitting diode of the present embodiment described above is substantially similar to semiconductor laser constructions, the present embodiment may be applied not only to GaN semiconductor lasers but also to GaP- and GaAlAs-based light emitting diodes.

Further, although the above embodiment has been described with reference to optical devices, it is to be understood that the present invention may be applied to electronic devices such as GaAs-based HBTs (Heterojunction Bipolar Transistors) and GaAlAs-based HEMTs (High Electron Mobility Transistors). Further, the present invention is not limited to Group III-V compound semiconductors, but may be applied to Group IV-based Si—Ge electronic devices.

The features and advantages of the present invention may be summarized as follows.

According to the first aspect of the present invention, there is provided a coating apparatus constructed such that when a plurality of layers are formed on a substrate by MOCVD, each layer can be deposited on the substrate in a separate coating chamber. Thus, it is not necessary to deposit these layers in the same coating chamber, which requires the replacement of one gas with another when switching between the deposition processes of these layers. This results in reduced time required for gas replacement. Further, it is possible to reduce impurities present due to insufficient gas replacement and thereby efficiently form a high quality deposition.

According to the second aspect of the present invention, there is provided a coating method for depositing a plurality of layers on a substrate by MOCVD, wherein each layer is deposited on the substrate in a separate coating chamber. This allows a reduction in the time required for gas replacement. Further, the susceptor on which the substrate is mounted is cleaned after the completion of the series of deposition processes on the substrate, thereby reducing foreign objects attached to the susceptor. Therefore, it is possible to efficiently form a high quality deposition.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2009-071133, filed on Mar. 24, 2009 including specification, claims, drawings and summary, on which the Convention priority of the present application is based, are incorporated herein by reference in its entirety.

What is claimed is:

1. A coating apparatus for performing a deposition process on a substrate placed in a coating chamber by metalorganic chemical vapor deposition, said coating apparatus comprising three or more said coating chambers, wherein said three or more coating chambers are configured such that each coating chamber is controlled independently of the other coating chambers to form a different film on said substrate by controlling at least the composition of the material gas, the flow rate of material gas, the temperature, and the pressure in the coating chamber.

2. The coating apparatus according to claim 1, wherein:
at least one of said three or more coating chambers is adapted to form an n-type GaN layer on a substrate, at least one of said three or more coating chambers is adapted to form an MQW (Multi-Quantum Well) active layer on a substrate, and at least one of said three or more coating chambers is adapted to form a p-type GaN layer on a substrate; and
the same substrate is transferred between said three or more coating chambers to manufacture a blue light emitting diode component by forming a film on said substrate in each coating chamber.

3. The coating apparatus according to claim 1, wherein:
each of said three or more coating chambers has a heater; and
said heater is one selected from the group consisting of an SiC heater, a tungsten (W) heater, a molybdenum (Mo) heater, and an RF coil.

4. The coating apparatus according to claim 1, further comprising:
transfer units for automatically transferring a susceptor, on which said substrate is mounted, between said three or more coating chambers; and
a cleaning unit provided outside said three or more coating chambers to clean said susceptor after said deposition process.

5. The coating apparatus according to claim 1, further comprising a substrate standby unit adjacent said three or more coating chambers, wherein said substrate standby unit has heating units for heating said substrate after said substrate is retrieved from said three or more coating chambers.

6. The coating apparatus according to claim 1, wherein:
each of said three or more coating chambers includes a susceptor table capable of rotating said susceptor on which said substrate is mounted; and
said deposition process is performed while rotating said substrate by rotating said susceptor table.

7. The coating apparatus according to claim 1, wherein said susceptor is capable of mounting a plurality of said substrates thereon.

8. The coating apparatus according to claim 7, wherein:
each of said three or more coating chambers includes a susceptor table capable of rotating said susceptor; and
said deposition process is performed while rotating said plurality of substrates by rotating said susceptor table.

9. The coating apparatus according to claim 7, further comprising:
transfer units for automatically transferring said susceptor between said three or more coating chambers; and
a cleaning unit provided outside said three or more coating chambers to clean said susceptor after said deposition process.

10. A coating method comprising:
automatically transferring a susceptor with a substrate mounted thereon from one to another of three or more different coating chambers such that a different film is deposited in a layer on said substrate in each coating chamber under different conditions by metalorganic chemical vapor deposition; and
removing a film attached to the surface of said susceptor by using a cleaning unit provided outside said three or more coating chambers;
wherein said different films layered on said substrate are an n-type GaN layer, a multiquantum well (MQW) active layer, and a p-type GaN layer.

11. The coating method according to claim 10, further comprising performing a deposition process on said substrate while rotating said substrate.

12. The coating method according to claim 10, further comprising:
transferring a plurality of said substrates into each of said three or more coating chambers; and
performing a deposition process on said plurality of substrates in each of said three or more coating chambers simultaneously.
